(19) United States
(12) Patent Application Publication
(10) Pub. No.: US 2025/0361624 A1
(43) Pub. Date: Nov. 27, 2025

(54) CONDUCTIVE SUBSTRATE HAVING HIGH THERMAL CONDUCTIVITY

(71) Applicant: CMTEK Co., Ltd., Hsinchu City (TW)

(72) Inventors: CHIN-JUI LIANG, Hsinchu City (TW); CHIN-PING LIN, Hsinchu City (TW)

(21) Appl. No.: 18/970,841

(22) Filed: Dec. 5, 2024

(30) Foreign Application Priority Data
May 22, 2024 (TW) 113205226

(51) Int. Cl. C23C 28/00; C04B 38/00; C04B 41/00; C04B 41/50; C04B 41/51; C04B 41/52; C23C 14/18; C23C 14/34; C23C 26/02; C25D 5/54; C25D 11/04; H05K 7/20

(52) U.S. Cl. CPC C23C 28/32; C04B 38/0051; C04B 41/009; C04B 41/5031; C04B 41/5035; C04B 41/5041; C04B 41/5127; C04B 41/5133; C04B 41/5144; C04B 41/5155; C04B 41/52; C23C 14/18; C23C 14/34; C23C 26/02; C23C 28/345; C25D 5/54; C25D 11/04; H05K 7/2039; C04B 2235/5436; C04B 2235/5445; C04B 2235/9607

(57) ABSTRACT

A conductive substrate having high thermal conductivity includes a heat spreader, an insulating layer, and a conductive layer. The insulating layer is formed on a surface of the heat spreader, and the conductive layer is formed on the insulating layer. The heat spreader includes a porous carrier and a metal surface layer coated on an outside of the porous carrier. The porous carrier is made of a ceramic material and/or a hard carbon material. The metal surface layer is made of a highly thermally conductive metal material, and pores of the porous carrier are filled with the highly thermally conductive metal material.

### CROSS-REFERENCE TO RELATED PATENT APPLICATION

This application claims the benefit of priority to Taiwan Patent Application No. 113205226, filed on May 22, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a conductive substrate, and more particularly to a conductive substrate having high thermal conductivity.

### BACKGROUND OF THE DISCLOSURE

Electronic products are constantly improving and updating. In order to meet the requirements of high integration, high transmission, high speed, and high efficiency, electronic products also require higher heat dissipation efficiency, in addition to providing basic functions. To improve heat dissipation the performance, a substrate structure of a circuit board is commonly embedded with thermally conductive members (such as ceramic or metal members) to provide thermally conductive paths in the thickness direction of the circuit board.

However, the processes involved with embedding the thermally conductive members into the substrate structure not only lead to a higher process complexity but also an increase in manufacturing costs, and result in problems relating to unreliable connection between the thermally conductive members and the substrate structure. In addition, the substrate structure exhibits a larger thermal resistance and a lower thermal diffusivity in the presence of the thermally conductive members, and is thus insufficient to meet heat dissipation requirements of servers and high power products, so that its range of application is also greatly restricted.

Therefore, how to provide an improvement in structure to overcome the above-referenced technical inadequacies has become one of the important issues in related industries.

### SUMMARY OF THE DISCLOSURE

In response to the above-referenced technical inadequacies, the present disclosure provides a conductive substrate having high thermal conductivity, which includes a composite of a highly thermally conductive metal material and at least one of a ceramic material and a hard carbon material, so as to be capable of adapting to severe thermal environmental conditions.

In order to solve the above-mentioned problems, one of the technical aspects adopted by the present disclosure is to provide a conductive substrate having high thermal conductivity, which includes a heat spreader, an insulating layer, and a conductive layer. The insulating layer is formed on a surface of the heat spreader, and the conductive layer is formed on the insulating layer. The heat spreader includes a porous carrier and a metal surface layer coated on an outside of the porous carrier. The porous carrier is made of a ceramic material and/or a hard carbon material. The metal surface layer is made of a highly thermally conductive metal material, and pores of the porous carrier are filled with the highly thermally conductive metal material.

In one of the possible or preferred embodiments, the insulating layer includes one or more composite layers, and the composite layers are each composed of a titanium dioxide layer, an aluminum oxide layer, and a silicon dioxide layer that are sequentially stacked from bottom to top.

In one of the possible or preferred embodiments, the conductive substrate further includes an interface layer that is formed between the insulating layer and the conductive layer. Furthermore, the conductive layer is made of copper, and the interface layer is made of nickel, chromium, titanium, or an alloy thereof.

In one of the possible or preferred embodiments, a thickness of the insulating layer ranges from 0.1 μm to 20 μm, a thickness of the conductive layer ranges from 2 μm to 100 μm, and a thickness of the interface layer ranges from 0.1 μm to 3 μm.

In one of the possible or preferred embodiments, the highly thermally conductive metal material is aluminum or an aluminum alloy, and the insulating layer is an anodized aluminum oxide layer.

In one of the possible or preferred embodiments, the conductive layer is a redistribution layer.

In one of the possible or preferred embodiments, the porous carrier is composed of small-size particles, mid-size particles, and large-size particles that are each independently silicon carbide, diamond, diamond-like carbon and/or graphene particles, and a particle size ratio of the small-size particles, the mid-size particles, and the large-size particles is 1:2-2.5:3-20.

In one of the possible or preferred embodiments, the porous carrier has a porosity from 20% to 70%.

In one of the possible or preferred embodiments, a particle size of the small-size particles ranges from 0.1 μm to 5 μm, a particle size of the mid-size particles ranges from 2 μm to 10 μm, and a particle size of the large-size particles ranges from 10 μm to 100 μm.

In one of the possible or preferred embodiments, a weight ratio of the small-size particles, the mid-size particles, and the large-size particles is 1:3:4, based on a total weight of the porous carrier.

In conclusion, the conductive substrate having high thermal conductivity provided by the present disclosure, by virtue of the heat spreader including a porous carrier and a metal surface layer coated on an outside of the porous carrier, the porous carrier being made of a ceramic material and/or a hard carbon material, the metal surface layer being made of a highly thermally conductive metal material, and pores of the porous carrier filled with the highly thermally conductive metal material, can provide a greatly improved heat dissipation performance to meet the requirements of high-power heat dissipation, and has characteristics required for practical applications, such as thermal stability, dielectric properties, and mechanical strength.

Furthermore, the conductive substrate having high thermal conductivity provided by the present disclosure not only has a wider range of applications but also a simple structure, and is easy to be manufactured at a lower production cost.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic structural view of a conductive substrate having high thermal conductivity of the present disclosure;

FIG. 2 is a schematic structural view of a heat spreader of the conductive substrate of the present disclosure;

FIG. 3 is a schematic enlarged view of part III of FIG. 2;

FIG. 4 is a schematic view of an insulating layer of the conductive substrate according to a different embodiment of the present disclosure; and

FIG. 5 is a schematic view of an optical communication module adopting the conductive substrate of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Unless otherwise stated, the material(s) used in any described embodiment is/are commercially available material(s) or may be prepared by methods known in the art, and the method(s) or operation(s) used in any described embodiment is/are conventional method(s) or operation(s) generally known in the related art.

### First Embodiment

Referring to FIG. 1, a first embodiment of the present disclosure provides a conductive substrate Z having high thermal conductivity, which mainly includes a heat spreader 1, an insulating layer 2, and a conductive layer 3. The insulating layer 2 is formed on a surface 100 (e.g., an upper surface) of the heat spreader 1, and the conductive layer 3 is formed on the insulating layer 2. It should be noted that, the heat spreader 1 is a composite of a highly thermally conductive metal material and at least one of a ceramic material and a hard carbon material, and is specifically formed by a porous carrier made of the ceramic material and/or the hard carbon material and carrying the highly thermally conductive metal material. Therefore, the conductive substrate Z of the present disclosure can adapt to severe thermal environmental conditions and provide characteristics required for practical applications such as mechanical strength.

Ceramic materials suitable for use in the present disclosure include, but are not limited to, silicon carbide, silicon dioxide, aluminum oxide, aluminum nitride, gallium nitride, and cubic boron nitride. Hard carbon materials suitable for use in the present disclosure include, but are not limited to, diamond, diamond-like carbon, and graphene. Highly thermally conductive metal materials suitable for use in the present disclosure include, but are not limited to, aluminum, copper, gold, silver, magnesium, titanium, nickel, and their alloys.

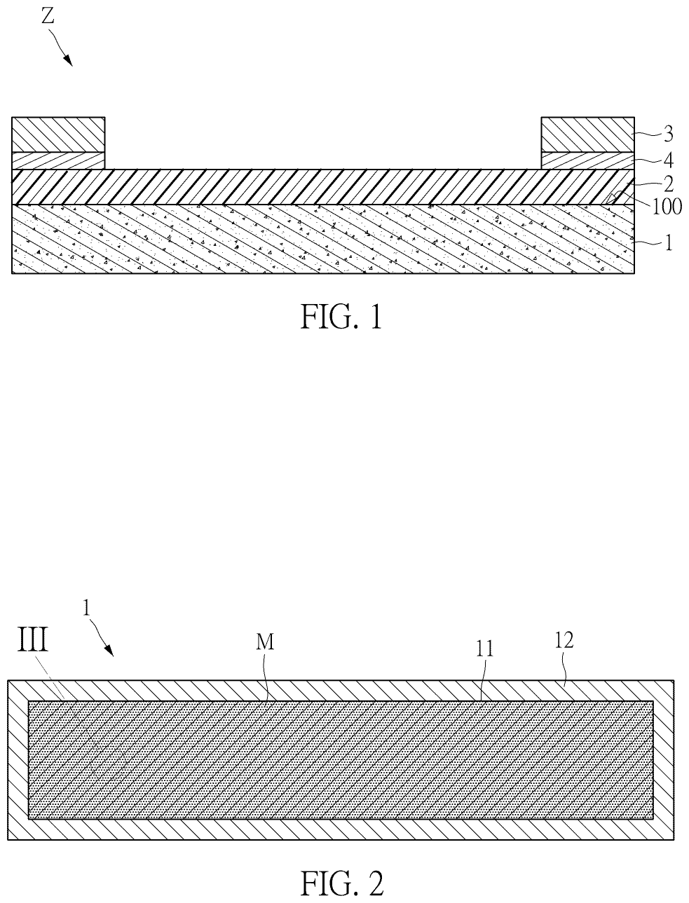

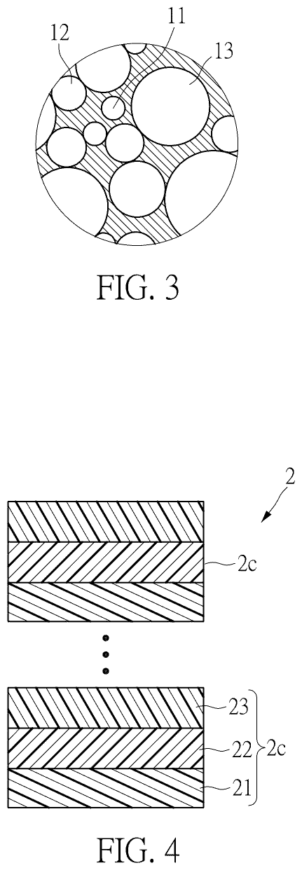

Reference is made to FIG. 2 and FIG. 3. The heat spreader 1 includes a porous carrier 11 and a metal surface layer 12 coated on an outside of the porous carrier 11. In the present disclosure, the porous carrier 11 is made of a ceramic material and/or a hard carbon material. The metal surface layer 12 is made of a highly thermally conductive metal material M, and pores of the porous carrier 11 are filled with the highly thermally conductive metal material M.

More specifically, the porous carrier 11 of the present disclosure is composed of small-size particles 111, mid-size particles 112, and large-size particles 113. A particle size ratio of the small-size particles 111, the mid-size particles 112, and the large-size particles 113 is 1:2-2.5:3-20. It should be noted that the particle size of each of the small-size particles 111, the mid-size particles 112, and the large-size particles 113 can vary with the thickness of the porous carrier 11. Preferably, the small-size particles 111, the mid-size particles 112, and the large-size particles 113 are each independently silicon carbide, diamond, diamond-like carbon, graphene particles, or any combination thereof. A weight ratio of the small-size particles 111, the mid-size particles 112, and the large-size particles 113 is 1:3:4, based on a total weight of the porous carrier 11.

In practice, the small-size particles 111, the mid-size particles 112, and the large-size particles 113 can be combined with each other by sintering to form the porous carrier 11. The porous carrier 11 can be formed into a block or sheet shape, but is not limited thereto. The porous carrier 1 has a porosity from 20% to 70%, i.e., a pore volume in the porous carrier 11 accounts for 20% to 70% of a total volume of the porous carrier 11. Furthermore, the particle size of the small-size particles 111 ranges from 0.1 μm to 5 μm, the particle size of the mid-size particles 112 ranges from 2 μm to 10 μm, and the particle size of the large-size particles 113 ranges from 10 μm to 100 μm. However, the above description is for exemplary purposes only, and is not meant to limit the scope of the present disclosure.

In one of the possible embodiments, the particle size of the small-size particles 111 can be 0.1 μm, 0.5 μm, 1 μm, 2 μm, 3 μm, 4 μm, or 5 μm. The particle size of the mid-size particles 112 can be 2 μm, 3 μm, 4 μm, 5 μm, 6 μm, 7 μm, 8 μm, 9 μm, or 10 μm. The particle size of the large-size particles 113 can be 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, or 100 μm.

Reference is made to FIG. 2. The metal surface layer 12 can be formed by performing an impregnation treatment with a metal melt on the porous carrier 11. More specifically, the metal melt contains the highly thermally conductive metal material M. The highly thermally conductive metal material M, under heating and specific pressure conditions, can be loaded on an external surface of the porous carrier 11 to form the metal surface layer 12 and penetrate into the pores of the porous carrier 11.

If necessary, mechanical processing (such as cutting, grinding, drilling, or grooving) can be performed on the porous carrier 11 before the impregnation treatment is performed, so as to form the porous carrier 11 into a desired shape or structure.

As shown in FIG. 1, an interface layer 4 that is formed between the insulating layer 2 and the conductive layer 3, so as to increase interface bonding strength. The conductive layer 3 can be made of copper and formed by electroplating. The interface layer 4 can be made of nickel, chromium, titanium, or an alloy thereof and formed by sputtering. However, such examples are not meant to limit the scope of the present disclosure.

In practice, the conductive layer 3 can be formed into a circuit layer, i.e., can have a predetermined circuit pattern with micron-level circuits. The interface layer 4 can have a pattern matching the circuit pattern of the conductive layer 3.

In one of the possible embodiments, a thickness of the insulating layer 2 ranges from 0.1 μm to 20 μm, a thickness of the conductive layer 3 ranges from 2 μm to 100 μm, and a thickness of the interface layer 4 ranges from 0.1 μm to 3 μm. For example, the thickness of the insulating layer 2 can be 0.1 μm, 1 μm, 5 μm, 10 μm, 15 μm, or 20 μm. The thickness of the conductive layer 3 can be 2 μm, 5 μm, 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, or 100 μm. The thickness of the interface layer 4 can be 0.1 μm, 0.5 μm, 1 μm, 1.5 μm, 2 μm, 2.5 μm, or 3 μm.

In one of the preferred embodiments, aluminum or an aluminum alloy can serve as the highly thermally conductive metal material M to form the metal surface layer 12, such that the insulating layer 2 can be formed by an anodizing treatment. That is, the insulating layer 2 is an anodized aluminum oxide layer. Furthermore, the conductive layer 3 can be formed into a redistribution layer. Therefore, the conductive substrate Z of the present disclosure does not require any interposer for installation in practical applications.

### Second Embodiment

Referring to FIG. 1 and FIG. 2, which is to be read in conjunction with FIG. 4, a second embodiment of the present disclosure provides a conductive substrate Z having high thermal conductivity, which mainly includes a heat spreader 1, an insulating layer 2, and a conductive layer 3. The insulating layer 2 is formed on a surface 100 (e.g., an upper surface) of the heat spreader 1, and the conductive layer 3 is formed on the insulating layer 2. The heat spreader 1 includes a porous carrier 11 and a metal surface layer 12 coated on an outside of the porous carrier 11. The porous carrier 11 is made of a ceramic material and/or a hard carbon material. The metal surface layer 12 is made of a highly thermally conductive metal material M, and pores of the porous carrier 11 are filled with the highly thermally conductive metal material M.

The main difference between the second embodiment and the first embodiment is as follows: in the second embodiment, the insulating layer 2 includes one or more composite layers 2c. The composite layers 2c are each composed of a titanium dioxide layer 21, an aluminum oxide layer 22, and a silicon dioxide layer 23 that are sequentially stacked from bottom to top. Therefore, the electrical insulation and dielectric characteristics of the conductive substrate Z can be improved. It should be noted that, in the composite layer 2c, the titanium dioxide layer 21 can enhance bonding strength, the aluminum oxide layer 22 can improve pressure resistance and structural strength, and the silicon dioxide layer 23 can provide a hole healing effect.

### Third Embodiment

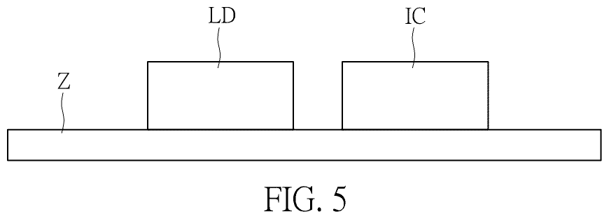

Referring to FIG. 5, a third embodiment of the present disclosure provides an optical communication module, which mainly includes a conductive substrate Z having high thermal conductivity, a laser diode LD, and an integrated circuit component IC. The laser diode LD and the integrated circuit component IC are disposed on the conductive substrate Z to convert electrical signals into optical signals for transmission. The technical details of the conductive substrate Z have been described in the first and second embodiments, and will not be reiterated herein.

### Beneficial Effects of the Embodiments

In conclusion, the conductive substrate having high thermal conductivity provided by the present disclosure, by virtue of the heat spreader including a porous carrier and a metal surface layer coated on an outside of the porous carrier, the porous carrier being made of a ceramic material and/or a hard carbon material, the metal surface layer being made of a highly thermally conductive metal material, and pores of the porous carrier filled with the highly thermally conductive metal material, can provide a greatly improved heat dissipation performance to meet the requirements of high-power heat dissipation, and has characteristics required for practical applications, such as thermal stability, dielectric properties, and mechanical strength.

Furthermore, the conductive substrate having high thermal conductivity provided by the present disclosure not only has a wider range of applications but also a simple structure, and is easy to be manufactured at a lower production cost.

Moreover, the metal surface layer of the heat spreader can be made of aluminum or an aluminum alloy, such that the insulating layer can be formed on a surface of the heat spreader by an anodizing treatment.

Moreover, the conductive substrate having high thermal conductivity provided by the present disclosure, in which the conductive layer is formed into a redistribution layer, does not require any interposer for installation in practical applications.

Moreover, the conductive substrate having high thermal conductivity provided by the present disclosure, in which the insulating layer includes one or more composite layers that are each composed of a titanium dioxide layer, an aluminum oxide layer, and a silicon dioxide layer that are sequentially stacked from bottom to top, can have good electrical insulation and dielectric performance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A conductive substrate having high thermal conductivity, comprising:
a heat spreader including a porous carrier and a metal surface layer coated on an outside of the porous carrier, wherein the porous carrier is made of a ceramic material and/or a hard carbon material, the metal surface layer is made of a highly thermally conductive metal material, and pores of the porous carrier are filled with the highly thermally conductive metal material;
an insulating layer formed on a surface of the heat spreader; and
a conductive layer formed on the insulating layer.

2. The conductive substrate according to claim 1, wherein the porous carrier is composed of small-size particles, mid-size particles, and large-size particles that are each independently silicon carbide, diamond, diamond-like carbon and/or graphene particles, and a particle size ratio of the small-size particles, the mid-size particles, and the large-size particles is 1:2-2.5:3-20.

3. The conductive substrate according to claim 1, wherein the porous carrier has a porosity ranging from 20% to 70%.

4. The conductive substrate according to claim 2, wherein a particle size of the small-size particles ranges from 0.1 μm to 5 μm, a particle size of the mid-size particles ranges from 2 μm to 10 μm, and a particle size of the large-size particles ranges from 10 μm to 100 μm.

5. The conductive substrate according to claim 2, wherein a weight ratio of the small-size particles, the mid-size particles, and the large-size particles is 1:3:4, based on a total weight of the porous carrier.

6. The conductive substrate according to claim 1, wherein the insulating layer includes one or more composite layers, and the composite layers are each composed of a titanium dioxide layer, an aluminum oxide layer, and a silicon dioxide layer that are sequentially stacked from bottom to top.

7. The conductive substrate according to claim 1, further comprising an interface layer that is formed between the insulating layer and the conductive layer, wherein the conductive layer is made of copper, and the interface layer is made of nickel, chromium, titanium, or an alloy thereof.

8. The conductive substrate according to claim 7, wherein a thickness of the insulating layer ranges from 0.1 μm to 20 μm, a thickness of the conductive layer ranges from 2 μm to 100 μm, and a thickness of the interface layer ranges from 0.1 μm to 3 μm.

9. The conductive substrate according to claim 7, wherein the highly thermally conductive metal material is aluminum or an aluminum alloy, and the insulating layer is an anodized aluminum oxide layer.

10. The conductive substrate according to claim 1, wherein the conductive layer is a redistribution layer.
